(19) United States
(12) Patent Application Publication
(10) Pub. No.: US 2026/0215066 A1
(43) Pub. Date: Jul. 23, 2026

(54) Display Device

(71) Applicant: LG Display Co., Ltd., Seoul (KR)

(72) Inventors: Seong-Han Hwang, Paju-si (KR); Kyung-Kook Jang, Paju-si (KR); Won-Rae Kim, Paju-si (KR); Hye-Jeong Park, Paju-si (KR); Seung-Cheol You, Paju-si (KR)

(21) Appl. No.: 19/345,470

(22) Filed: Sep. 30, 2025

(30) Foreign Application Priority Data
Jan. 20, 2025 (KR) 10-2025-0008266

(51) Int. Cl. H10H 29/80; H10H 29/37; H10H 29/855; H10K 59/122; H10K 59/80

(52) U.S. Cl. CPC H10H 29/882; H10H 29/37; H10H 29/855; H10K 59/122; H10K 59/877; H10K 59/879

(57) ABSTRACT

A display device in some examples can comprise a light-diffusion coating layer in which a scattering particle is dispersed between a first electrode of a light-emitting diode and a bank layer. External light incident on the display device collides with the scattering particle and scatters, and is absorbed by the bank layer having a light blocking material. The image quality can be improved by preventing rainbow mura and/or diffraction mura due to the reflection of the external light. It is possible to secure the reliability and pattern processability when the bank is disposed by introducing the light-diffusion coating layer that scatters the external light independently.

### CROSS-REFERENCE TO RELATED APPLICATION

This application claims priority under 35 U.S.C. § 119(a) to the Republic of Korea Patent Application No. 10-2025-0008266, filed in the Republic of Korea on Jan. 20, 2025, the entire contents of which are hereby expressly incorporated by reference into the present application.

### TECHNICAL FIELD

The present disclosure relates to a display device, and more particularly to, a display device capable of minimizing stains due to a reflection of an external light and securing reliability and processability by preventing the reflection of the external light.

### BACKGROUND ART

Display devices that display image in electronic apparatuses such as TV, a monitor, a smartphone, a tablet PC and a note-book includes various types and shapes. For example, the display devices include a display panel that has a plurality of light-emitting diodes or liquid crystals for implementing images and a transistor for controlling each light-emitting diode or the liquid crystal. The display devices display intended images through the plurality of light-emitting diodes or liquid crystals constituting the display panel.

Technologies for the light emitting display device including the light-emitting diode as the display devices have been developed rapidly. The light emitting display device can be divided into an organic light emitting display device using an organic luminescent material and an inorganic light emitting display device using an inorganic luminescent material.

The display device including the light emitting display device includes a polarizer on the display surface to minimize a reflection of an external light. Recently, various researches and developments for improving the reliability and image quality of the display devices have been performed.

### SUMMARY

Accordingly, one or more embodiments of the present disclosure are directed to a display device that substantially obviates one or more of the problems due to the limitations and disadvantages of the related art.

An aspect of the present disclosure is to provide a display device capable of minimizing a reflection of an external light with maintaining or improving luminance or preventing decrease of the luminance.

Another aspect of the present disclosure is to provide a display device capable of minimizing stains and/or a rainbow mura, which is caused by a light reflection of a conductive material such as a conductive film and/or an electrode in the display panel and refractive index differences of films through which the reflective light is passed through.

Another aspect of the present disclosure is to provide a display device capable of securing process reliability and pattern processability with regard to an arrangement and a formation of a bank layer.

Another aspect of the present disclosure is to provide a display device capable of improving flexibility and applying to a foldable product.

Another aspect of the present disclosure is to provide a display device capable of removing a polarizing member.

Another aspect of the present disclosure is to provide a display device with a beneficial viewing angle.

Another aspect of the present disclosure is to provide a display device that implements low reflection and low power, thereby being environmentally friendly and pursuing ESG (Environmental, Social, and Governance).

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, the present disclosure provides a display device that comprises a substrate having an emission area and a non-emission area; a light-emitting diode disposed on the substrate correspondingly to the emission area, wherein the light-emitting diode includes a first electrode, a second electrode facing to the first electrode and an emissive layer between the first electrode and the second electrode; a light-diffusion coating layer disposed on a peripheral areal of the first electrode, wherein the light-diffusion coating layer includes a scattering particle, and a first binder resin in which the scattering particles are dispersed; and a bank layer disposed correspondingly to the non-emission area outside of the light-emitting diode and covering the peripheral area of the first electrode and the light-diffusion coating layer.

The scattering particle may have a refractive index different from a refractive index of the first binder resin.

In another embodiment, the scattering particle may have a refractive index different from a refractive index of the bank layer.

For example, the scattering particle may have a refractive index lower than refractive indices of the first binder resin and the bank layer.

The bank layer may include a light-blocking material; and a second binder resin in which the light-blocking material is dispersed.

The scattering particle may have a refractive index different from refractive indices of the first binder resin and the second binder resin, respectively.

In one embodiment, the light-blocking material may include at least one of a black dye and a black pigment.

The first binder resin may have a refractive index equal to or more than a refractive index of the second binder resin.

In one embodiment, the light-diffusion coating layer may have a surface configured to have a cross-section parallel to a surface of the first electrode.

For example, a side of the bank layer in contact with an outside of the light-emitting diode may have a cross-sectional shape inclined downwardly toward the light-emitting diode.

In another embodiment, the light-diffusion coating layer may include a surface with an upwardly protruding cross-sectional shape.

In another embodiment, the scattering particle may include surfaces with a porous structure with a plurality of pores, or the scattering particle may have a hollow structure.

For example, the scattering particle may comprise an inorganic oxide selected from silicon monoxide (SiO), silicon dioxide (SiO₂), aluminum oxide (Al₂O₃), magnesium oxide (MgO), hafnium oxide (HfO₂), lutetium oxide (LuO₂), molybdenum oxide (MoO₃), niobium pentoxide (Nb₂O₅), scandium oxide (Sc₂O₃), tantalum pentoxide (Ta₂O₅), tungsten oxide (WO₃), yttrium oxide (Y₂O₃), tellurium oxide (TeO₂), titanium oxide (TiO₂), vanadium oxide (VO₂), zinc oxide (ZnO), zirconium oxide (ZrO₂), lutetium aluminum oxide (Lu₃Al₅O₁₂), scandium aluminum magnesium oxide (ScAlMgO₄), terbium gallium oxide (Tb₃Ga₅O₁₂), yttrium aluminum oxide (Y₃Al₅O₁₂), and combinations thereof.

In another embodiment, the scattering particle may comprise an inorganic fluoride selected from magnesium fluoride (MgF₂), lithium fluoride (LiF), potassium fluoride (KF), lithium calcium aluminum fluoride (LiCaAlF₆), sodium fluoride (NaF), rubidium fluoride (RbF), strontium fluoride (SrF₂), and combinations thereof.

For example, a difference between a refractive index of the scattering particle and a refractive index of the first binder resin may be about 0.1 to about 2.0.

A difference between a refractive index of the scattering particle and a refractive index of the first binder resin and the second binder resin may be about 0.1 to about 2.0, respectively.

For example, the scattering particle may have a refractive index between about 1.75 and about 3.5.

The scatting particle may have an average size between about 100 nm and about 1000 nm.

The display device may further comprise a driving thin film transistor disposed on the substrate and connected to the light-emitting diode; an encapsulation layer disposed on the light-emitting diode and the bank layer; a color filter layer disposed on the encapsulation layer correspondingly to the emission area; and a black matrix disposed on the encapsulation layer correspondingly to the non-emission area.

For example, a side of the bank layer in contact with the light-emitting diode may extend toward the emission area compared to a side of the black matrix in contact with the color filter layer.

The driving thin film transistor may include an oxide semiconductor.

In one or more embodiments, the luminance of the display device may not be reduced since there is no need to apply a separate polarizing member on the display surface. The external light is scattered and diffused by the scattering particles included in the light-diffusion coating layer, the bank layer including the light blocking material such as black colorant. Accordingly, the external light is absorbed and blocked so that the reflection of the external light can be minimized.

As the reflection of external light minimizes, it is possible to reduce or minimize stains and the rainbow mura phenomenon due to the light reflection in the conducive materials such as conductive films and/or electrodes in the display panel and the differences of refractive indices between the films in which the reflected light is passed through.

In accordance with the present disclosure, since there is no need to apply a separate polarizer on the display surface, the luminance of light emitted from the light-emitting diode is not reduced. The clearly recognized external light can be absorbed and/or blocked by the anti-reflection pattern and/or the column spacer. In addition, the external light reflection and stains caused by the external light reflection can be further minimized by disposing the bank layer including the black colorant.

In accordance with the present disclosure, the display device can remove the polarizing member to improve flexibility thereof, and therefore, it is possible to implement a foldable display device in which the display area is foldable.

The reliability of the black bank layer can be improved with maintaining sufficient optical density of the black bank layer. In addition to the bank layer including the black colorant, the light-diffusion coating layer including the scattering particle is disposed on the peripheral area of the electrode. Since the bank layer does not include any scattering particle except the black colorant, the reliability and processability of the bank layer pattern, which may be caused in curing the binder rein in the bank layer, may not be reduced.

Since the side of the bank layer disposed adjacently to the light-emitting diode further extends toward the emission area compared to the side of the black matrix disposed adjacently to the color filter layer, the display device can secure beneficial viewing angles.

In addition, a low-reflection display device can be implemented, and ESG can be implemented proving the advantage of low power by disposing the black bank layer and/or the light-diffusion coating layer including the scattering particles.

It is to be understood that both the foregoing general description and the following detailed description are examples and explanatory, and are intended to provide further explanation of the inventive concepts as claimed.

### BRIEF DESCRIPTION OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates a schematic circuit diagram of a display device in one or more embodiments of the present disclosure.

FIG. 2 illustrates a schematic cross-sectional view of the display device in a first embodiment of the present disclosure.

FIG. 3 is a schematic diagram illustrating component and configurations of a light-emitting diode, a light-diffusion coating layer and a bank layer in the display device in accordance with the first embodiment of the present disclosure.

FIG. 4 is a schematic diagram illustrating that the external light reflection is minimized in the display device in accordance with the first embodiment of the present disclosure.

FIG. 5 is a schematic enlarged diagram of the “A” area in FIG. 4.

FIG. 6 illustrates a schematic cross-sectional view of the display device in a second embodiment of the present disclosure.

FIG. 7 is a schematic diagram illustrating components and configurations of a light-emitting diode, a light-diffusion coating layer and a bank layer in the display device in accordance with the second embodiment of the present disclosure.

FIG. 8 is a schematic diagram illustrating that the external light reflection is minimized in the display device in accordance with the second embodiment of the present disclosure.

FIG. 9 is a schematic enlarged diagram the “B” area in FIG. 8.

FIG. 10 illustrates a schematic exploded perspective view of a display device in accordance with a third embodiment of the present disclosure.

FIG. 11 illustrates a schematic cross-sectional view of the display device in accordance with the third embodiment of the present disclosure.

FIGS. 12 to 14 are photographs illustrating simulation results for the reflection of external light in the display device where no light-diffusion coating layer is disposed on the surface of the first electrode constituting the light-emitting diode and in the display device where the light-diffusion coating layer is disposed between the first electrode and the bank layer.

### DETAILED DESCRIPTION OF THE EMBODIMENTS

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing embodiments of the present disclosure are merely illustrative examples, and thus the present disclosure is not limited to the illustrated examples. The same reference numerals refer to the same components throughout this disclosure unless otherwise specified. Further, in the following description of the present disclosure, where a detailed description of a known related art can unnecessarily obscure the gist of the present disclosure, the detailed description thereof can be omitted herein or can be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified.

In analyzing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

When a component or layer is referred to as being “on” another component or layer, it includes both instances where the component is directly on the other component or layer, or where there is another layer or component intervening therebetween.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included. Further, the term “can” fully encompass all the meanings and coverages of the term “may” and vice versa.

Although the terms first, second, and the like can be used to describe various components, these components are not substantially limited by these terms. These terms are used only to refer to one component separately from another component, and may not define any particular order or sequence. Therefore, a first component described below can substantially be a second component, and vice versa, within the technical spirit of the present disclosure.

Features of various embodiments of the present disclosure can be partially or entirely united or combined with each other, technically various interlocking and driving are possible, and each of the embodiments can be independently implemented with respect to each other or implemented together in a co-dependent relationship.

All the components of each display device according to all embodiments of the present disclosure are operatively coupled and configured.

Reference will now be made in detail to aspects of the disclosure, examples of which are illustrated in the accompanying drawings. Wherever possible, the same reference numbers will be used throughout the drawings to refer to the same or like parts.

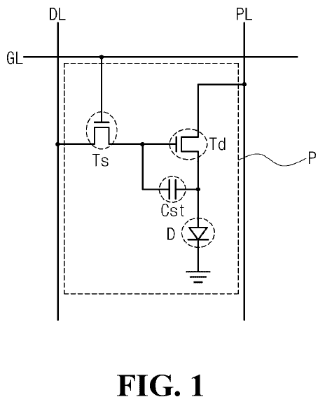

FIG. 1 illustrates a schematic circuit diagram of a light emitting display device in one or more embodiments of the present disclosure.

Referring to FIG. 1, the display device in accordance with the present disclosure includes a gate line GL, a data line DL and a power line PL crossing each other to define a pixel region P. A switching thin film transistor Ts, a driving thin film transistor Td, a storage capacitor Cst and a light-emitting diode D can be disposed in the pixel region P. A pixel region P can comprise a first sub-pixel region, a second sub-pixel region, a third sub-pixel region, and optionally, a fourth sub-pixel region. As an example, the first sub-pixel region can be a red (R) sub-pixel region, the second sub-pixel region can be a green (G) sub-pixel region, the third sub-pixel region can be a blue (B) sub-pixel region, and the fourth sub-pixel region can be a white (W) sub-pixel region, but is not limited thereto.

The switching thin film transistor Ts is connected to the gate line GL and the data line DL. The driving thin film transistor Td and the storage capacitor Cst are connected between the switching thin film transistor Ts and the power line PL, and the light-emitting diode D is connected to the driving thin film transistor Td.

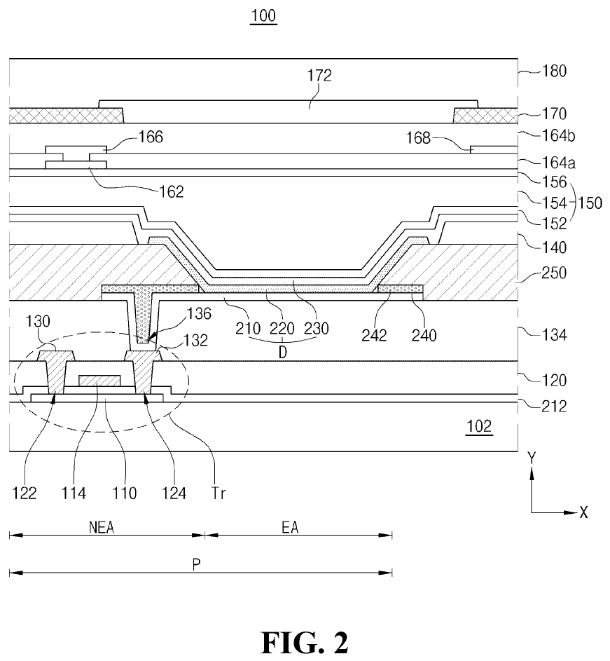

In the display device, when the switching thin film transistor Ts is turned on by a gate signal applied to the gate line GL, a data signal applied to the data line DL is applied a gate electrode 114 (with reference to FIG. 2) and one electrode of the storage capacitor Cst through the switching thin film transistor Ts.

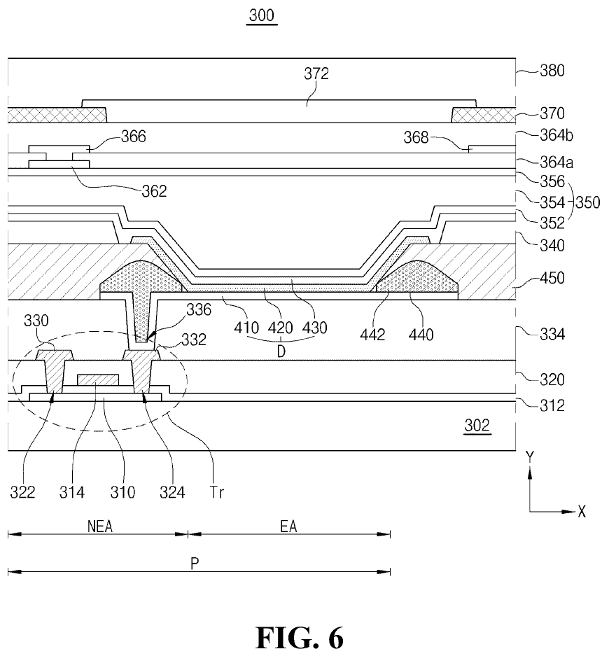

The driving thin film transistor Td is turned on by the data signal applied to the gate electrode 114 so that a current proportional to the data signal is supplied from the power line PL to the light-emitting diode D through the driving thin film transistor Td. And then, the light-emitting diode D emits light having a luminance proportional to the current flowing through the driving thin film transistor Td. In this case, the storage capacitor Cst is charged with a voltage proportional to the data signal so that the voltage of the gate electrode 114 in the driving thin film transistor Td is kept constant during one frame. Therefore, the display device 100 or 300 (FIG. 2 or FIG. 6) can display a desired image.

In one embodiment, each of the switching thin film transistor Ts and/or the driving thin film transistor Td can comprise, but is not limited to, a polycrystalline semiconductor material such as low temperature polycrystalline silicon (LTPS) and/or an oxide semiconductor. For example, the switching thin film transistor Ts and/or the driving thin film transistor Td can be a transistor of a low temperature polycrystalline and oxide (LPTO) type including the LPTS and the oxide semiconductor, but is not limited thereto. In another embodiment, the driving thin film transistor Td can be a transistor of a Complementary Metal Oxide Semiconductor (CMOS) type combining a p-Channel Metal Oxide Semiconductor (PMOS) and an n-Channel Metal Oxide Semiconductor (NMOS), but is not limited thereto.

### First Embodiment

FIG. 2 illustrates a schematic cross-sectional view of the display device in a first embodiment of the present disclosure.

Referring to FIG. 2, a display device 100 includes a substrate 102, and a light-emitting diode D, and optionally, a thin film transistor Tr disposed on the substrate 102 and a color filter layer 172 disposed on the light-emitting diode D.

The pixel region P (FIG. 1) including the red sub-pixel, the green sub-pixel and the blue sub-pixel can be defined in the substrate 102. The pixel region P can further include the white sub-pixel. In addition, the substrate 102 can comprise an emission area EA and a non-emission area NEA disposed adjacently to the emission area EA or surrounds the emission area EA.

The substrate 102 can comprise, but is not limited to, a glass substrate, a flexible substrate or a polymer plastics substrate. For example, the substrate 102 can be configured to have at least one of a polyimide (PI) substrate, a polyether sulfone (PES) substrate, a polyethylene naphthalate (PEN) substrate, a polyethylene terephthalate (PET) substrate and a polycarbonate (PC) substrate.

The thin film transistor Tr is disposed on the substrate 102. In FIG. 2, the thin film transistor Tr is disposed directly on the substrate 102. Alternatively, a first buffer layer can be disposed on the substrate 102 and the thin film transistor Tr can be disposed on the first buffer layer. For example, the first buffer layer can comprise, but is not limited to, silicon oxide (SiOₓ) and/or silicon nitride (SiNₓ,) (wherein 0<X≤2).

The thin film transistor Tr can comprise a semiconductor layer 110, a gate electrode 114, a source electrode 130 and a drain electrode 132. The thin film transistor Tr can be the driving thin film transistor Td (FIG. 1).

The semiconductor layer 110 is disposed on the substrate 102. In one embodiment, the semiconductor layer 110 can comprise an oxide semiconductor material. For example, the oxide semiconductor can be selected from, but is not limited to, Indium Gallium Zinc oxide (IGZO), Indium Zinc Tin oxide (IZTO), Zinc Gallium Tin oxide (ZGTO), Zinc Tin oxide (ZTO), Zinc Gallium oxide (ZGO), Zinc oxide (ZnO) and combinations thereof.

When the semiconductor layer 110 comprises the oxide semiconductor material, a light shielding pattern can be disposed under the semiconductor layer 110. The light shielding pattern can prevent the light from being incident to the semiconductor layer 110, and thereby the semiconductor layer 110 from being deteriorated by the light. In another embodiment, the semiconductor layer 110 can comprise a polycrystalline semiconductor. In this case, impurity can be doped to both sides of the semiconductor layer 110.

A gate insulating layer 212 can be disposed on the semiconductor layer 110 with covering the entire substrate 102. For example, the gate insulating layer 212 can comprise, but is not limited to, an inorganic insulating material such as silicon oxide (SiOₓ) and/or silicon nitride (SiNₓ) (wherein 0<x≤2).

The gate electrode 114 including a conductive material such as metal is disposed on the gate insulating layer 212 corresponding to a center of the semiconductor layer 110. For example, the gate electrode 114 can comprise, but is not limited to, a metal component such as copper (Cu), molybdenum (Mo), titanium (Ti), aluminum (Al), gold (Au), and silver (Ag). The gate electrode 114 can have a mono-layer structure or a multi-layer structure. In FIG. 2, while the gate insulating layer 212 can be disposed on the entire substrate 102, the gate insulating layer 212 can be patterned as the gate electrode 114.

An interlayer insulating layer 120 is disposed on the gate electrode 114 with covering the entire substrate 102. For example, the interlayer insulating layer 120 can comprise, but is not limited to, an inorganic insulating material such as silicon oxide (SiOₓ) and silicon nitride (SiNₓ) (wherein 0<x≤2) or an organic insulating material such as benzocyclobutene and/or photo-acryl.

The interlayer insulating layer 120 has first and second semiconductor contact holes 122 and 124 that expose or do not cover the both sides of the semiconductor layer 110. The first and second semiconductor contact holes 122 and 124 are located spaced apart from the gate electrode 114 at both sides of the gate electrode 114. In FIG. 2, the first and second semiconductor contact holes 122 and 124 are disposed in the interlayer insulating layer 120 and the gate insulating layer 212. In another embodiment, when the gate insulating layer 212 is patterned as the gate electrode 114, the first and second semiconductor contact holes 122 and 124 can be formed in only the interlayer insulating layer 120.

The source electrode 130 and the drain electrode 132 comprising a conductive material such as metal component are disposed on the interlayer insulating layer 120. The source electrode 130 and the drain electrode 132 are spaced apart from each other with centering the gate electrode 114, and contact to both sides of the semiconductor layer 110 through the first and second semiconductor contact holes 122 and 124. In one embodiment, the source electrode 130 can be an input electrode connecting to a high potential driving power and the drain electrode 132 can be an output electrode connecting to a switch circuit, but is not limited thereto. The amount of current flowing to the light-emitting diode D can be controlled by voltage differences between the gate electrode 114 and the source electrode 130.

For example, the source electrode 130 and the drain electrode 132 can comprise, but is not limited to, the metal component such as copper (Cu), molybdenum (Mo), titanium (Ti), aluminum (Al), gold (Au) and/or silver (Ag). The source electrode 130 and the drain electrode 132 can have a mono-layer structure or a multi-layer structure.

In FIG. 2, the thin film transistor Tr has a coplanar structure where the gate electrode 114, the source electrode 130 and the drain electrode 132 are disposed on the semiconductor layer 110. In another embodiment, the thin film transistor can have an inverted staggered structure where the gate electrode is disposed under the semiconductor layer and the source electrode and the drain electrode are disposed on the semiconductor layer. In this case, the semiconductor layer can comprise amorphous silicon.

The thin film transistor Tr can be the driving thin film transistor Td (FIG. 1). For example, the driving thin film transistor Td can comprise the oxide semiconductor, but is not limited thereto.

A planarization layer 134 is disposed on the source electrode 130 and the drain electrode 132 with covering the entire substrate 102. The planarization layer 134 can be disposed with covering the thin film transistor Tr.

The planarization layer 134 has a flat surface and has a drain contact hole 136 that exposes or do not cover the drain electrode 132. For example, the planarization layer 134 can comprise, but is not limited to, an inorganic insulating material such as silicon oxide (SiOₓ) and silicon nitride (SiNₓ) (wherein 0<x ≤2) or an organic insulating material such as benzocyclobutene and/or photo-acryl.

The light-emitting diode D is disposed on the planarization layer 134 correspondingly to the emission area EA. The light-emitting diode comprises a first electrode 210 disposed on the planarization layer 134 and connected to the source electrode 130 or the drain electrode 132, and an emissive layer 220 and a second electrode 230 that are laminated sequentially on the first electrode 210. As an example, the light-emitting diode D can be positioned in each of the red sub-pixel, the green sub-pixel and the blue sub-pixel and can emit red light, green light and blue light, respectively. In another embodiment, the light-emitting diode D can emit white light in each sub-pixel.

The first electrode 210 can be disposed separately in each sub-pixel region. The first electrode 210 can be an anode and can comprise a conductive material with relatively high work function value, for example, a transparent conductive oxide (TCO). For example, the first electrode 210 can comprise, but is not limited to, Indium Tin oxide (ITO), Indium Zinc oxide (IZO), Indium Tin Zinc oxide (ITZO), Tin oxide (SnO), Zinc oxide (ZnO), Indium Copper oxide (ICO) and/or Aluminum: Zinc oxide (AZO).

In one embodiment, the first electrode 210 can have a mono-layer structure of the transparent conductive oxide. In another embodiment, the first electrode 210 can have a bi-layer structure or a triple-layer structure with further comprising a reflective layer. In this case, the first electrode 210 can be a reflective electrode.

In one embodiment, the reflective layer can comprise, but is not limited to, silver (Ag), an alloy including silver (Ag) and at least one of palladium (Pd), copper (Cu), indium (In) and neodymium (Nd), and/or an aluminum-palladium-copper (APC) alloy. For example, the first electrode 210 can have a bi-layer structure of Ag/ITO or APC/ITO or a triple-layer structure of ITO/APC/ITO.

A light-diffusion coating layer 240 covering a peripheral area, that is, an edge of the first electrode 210 and a bank layer 250 covering the peripheral area of the first electrode 210 and the light-diffusion coating layer 240 are disposed correspondingly to the non-emission area NEA on the planarization layer 134.

The bank layer 250 exposes or do not cover the center of the first electrode 210 corresponding to the sub-pixel region. For example, the bank layer 250 can comprise a black material, a light-blocking or light-absorbing material. Alternatively, the bank layer 250 can be configured to have a structure where color filter layers including at least two different colorants among red, green and/or blue colorants can be laminated.

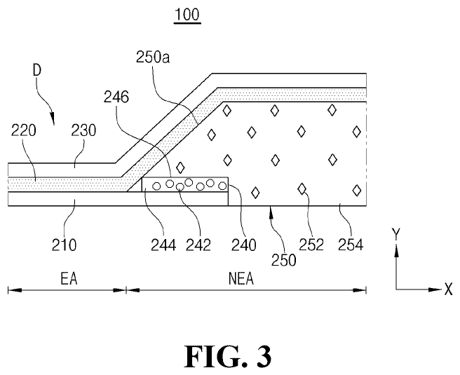

In accordance with the first embodiment, the light-diffusion coating layer 240 including a plurality of scattering particles 242 is disposed between a peripheral surface of the first electrode 210 constituting the light-emitting diode D and the bank layer 250. The light-diffusion coating layer 240 may have a surface 246 (FIG. 3) with a cross-sectional shape substantially parallel to the surface of the first electrode 210.

The stains caused by the reflection of the external light can be reduced or minimized by applying the light-diffusion coating layer 240 in which the scattering particle 242 (FIG. 3) is dispersed. In addition, the patterned bank layer 250 may be disposed in the non-emission area NEA with securing the reliability and processability in the process by introducing the scattering particle 242 in the light-diffusion coating layer 240. As an example, the bank layer 250 can comprise a light-absorbing and/or light-blocking material 252 (FIG. 3).

A column spacer 140 is disposed on the bank layer 250. The column spacer 140 can be disposed to surround the emission area EA where the light-emitting diode D is disposed in each sub-pixel region. The column spacer 140 may have the same material as the bank layer 250. For example, the column spacer 140 can comprise a light-blocking and/or light-absorbing material.

For example, the column spacer 140 can have a cross-sectional shape of which the width gradually increases toward the bank layer 250 (a trapezoidal cross-sectional shape or a tapered shape), or a cross-sectional shape of which the width gradually decreases toward the bank layer 250 (an inverted-trapezoidal cross-sectional shape or an inverted-taper shape), but is not limited thereto.

The emissive layer 220 is disposed on the first electrode 210. As an example, the emissive layer 220 can have a mono-layer structure of an emitting material layer (EML). The EML can comprise an organic luminescent material or an inorganic luminescent material. In other words, the light emitting display device 100 may be an organic light emitting display device or an inorganic light emitting display device, but is not limited thereto.

In the organic light emitting display device, the EML can comprise a host and a dopant as an emitter. The EML can comprise a red host and a red dopant in the red sub-pixel. The EML can comprise a green host and a green dopant in the green sub-pixel. The EML can comprise a blue host and a blue dopant in the blue sub-pixel. In the inorganic light emitting display device, the EML can comprise quantum dots as the inorganic luminescent material.

In another embodiment, the emissive layer 220 may have a multi-layer structure. As an example, the multi-layered emissive layer 220 can further comprise at least one of a hole injection layer (HIL), a hole transport layer (HTL), an electron blocking layer (EBL), a hole blocking layer (HBL), an electron transport layer (ETL) and an electron injection layer (EIL) in addition to the EML.

In one embodiment, the light-emitting diode D can emit white light in each of the red sub-pixel, the green sub-pixel and the blue sub-pixel. For example, the emissive layer 220 of the light-emitting diode D can have a double-stack structure including a first emitting part including a first emitting material layer, a second emitting part including a second emitting material layer and a charge generation layer (CGL) disposed between the first emitting part and the second emitting part. In another embodiment, the emissive layer 220 of the light-emitting diode D can have a triple-stack structure further including a third emitting part including a third emitting material layer and another charge generation layer between the second emitting part and the third emitting part.

The second electrode 230 is disposed on the substrate 102 onto which the emissive layer 220 is disposed. The second electrode 230 can be disposed on the entire display area and can comprise a conductive material with relatively low work function value to act as a cathode. For example, the second electrode 230 can comprise, but is not limited to, aluminum (Al), magnesium (Mg), calcium (Ca), silver (Ag), and alloys thereof such as magnesium silver alloy. The second electrode 230 can have a thin thickness to have a light-transmissive (semi-transmissive) property.

An encapsulation layer (encapsulation film) 150 is disposed on the second electrode 230 in order to prevent external oxygen and/or moisture from infiltrating to the light-emitting diode D. In one embodiment, the encapsulation layer 150 can have, but is not limited to, a lamination structure of a first inorganic insulating layer 152, an organic insulating layer 154 and a second inorganic insulating layer 156.

Each of the first inorganic insulating layer 152 and the second inorganic insulating layer 156 can comprise, but is not limited to, an inorganic insulating material such as silicon oxide (SiOₓ) and silicon nitride (SiNₓ) (wherein 0<x≤2). The organic insulating layer 154 can comprise, but is not limited to, an organic insulating material such as an epoxy resin, photo-acryl (or photosensitive acrylic polymer). The organic insulating layer 154 is disposed between the first inorganic insulating layer 152 and the second inorganic insulating layer 156. The organic insulating layer 154 makes the lower step to flatten and provides a flat surface.

A touch sensor or a touch panel can be disposed on the encapsulation layer 150 to provide a sensing function. As an example, the touch sensor can comprise a connection (or bridge) electrode 162 disposed on the encapsulation layer 150, a first touch insulating layer 164a having first and second contact holes exposing both sides of the connection electrode 162, a first touch electrode 166 and a second touch electrode 168 disposed on the first touch insulating layer 164a, and a second touch insulating layer 164b disposed on the first and second touch electrodes 166 and 168. Adjacent first touch electrodes 166 can be connected to the connection electrode 162 through the first and second contact holes and can be electrically connected to each other.

For example, the first touch insulating layer 164a can comprise, but is not limited to, an inorganic insulating material such as silicon oxide (SiOₓ) and/or silicon nitride (SiNₓ,) (wherein 0<x≤2).

Alternatively, or additionally, a second buffer layer can be disposed between the second inorganic insulating layer 156 of the encapsulation layer 150 and the first touch insulating layer 164a. The second buffer layer can comprise, but is not limited to, an inorganic insulating material such as silicon oxide (SiOₓ) and/or silicon nitride (SiNₓ,) (wherein 0<x≤2). For example, the second touch insulating layer 164b can comprise, but is not limited to, an inorganic insulating material such as silicon oxide (SiOₓ) and/or silicon nitride (SiNₓ,) (wherein 0<x≤2), or an organic insulating material such as benzocyclobutene or photo-acryl. For example, the touch electrodes 166 and 168 can comprise, but is not limited to, a transparent metal oxide such as ITO, IZO, ITZO, SnO, ZnO, ICO and/or AZO.

A black matrix 170 and a color filter layer 172 are disposed on the second touch insulating layer 164b. In another embodiment, the touch sensor including the connection electrode 162, the first touch insulating layer 164a, a first touch electrode 166, a second touch electrode 168 and the second touch insulating layer 164b can be omitted, and the black matrix 170 and the color filter layer 172 can be disposed on the encapsulation layer 150.

The black matrix 170 is disposed in a periphery of the sub-pixel region corresponding to the non-emission area NEA and has an opening corresponding to the light-emitting diode D. For example, the black matrix 170 can comprise a light-shielding material or a light-absorbing material such as a black resin and/or carbon black. Alternatively, or additionally, a color filter layer including a red (R), green (G) and/or blue (B) colorants can be laminated on the black matrix 170.

The color filter layer 172 is disposed corresponding to the openings of the black matrix 170. In other words, the color filter layer 172 is disposed on the encapsulation layer 150 or the touch sensor correspondingly to the emission area EA. When the sub-pixel region includes the red sub-pixel, the green sub-pixel and the blue sub-pixel, the color filter layer 172 can comprise a red color filter pattern corresponding to the red sub-pixel, a green color filter pattern corresponding to the green sub-pixel and a blue color filter pattern corresponding to the blue sub-pixel.

The red color filter pattern can comprise at least one of a red dye and a red pigment. The green color filter pattern can comprise at least one of a green dye and a green pigment. The blue color filter pattern can comprise at least one of a blue dye and a blue pigment.

In another embodiment, a passivation layer is disposed on the second touch insulating layer 164b with covering the entire substrate 102, and the black matrix 170 and the color filter layer 172 can be disposed on the passivation layer. The passivation layer can comprise, but is not limited to, an inorganic insulating material such as silicon oxide (SiOₓ) and/or silicon nitride (SiNₓ) (wherein 0<X≤2).

A first insulating layer 180 can be disposed on the color filter layer 172 with covering the entire substrate 102. For example, the first insulating layer 180 can comprise, but is not limited to, an organic insulating material such as an epoxy-containing resin and/or photo-acryl. Alternatively, or additionally, a second insulating layer can be disposed on the first insulating layer 180.

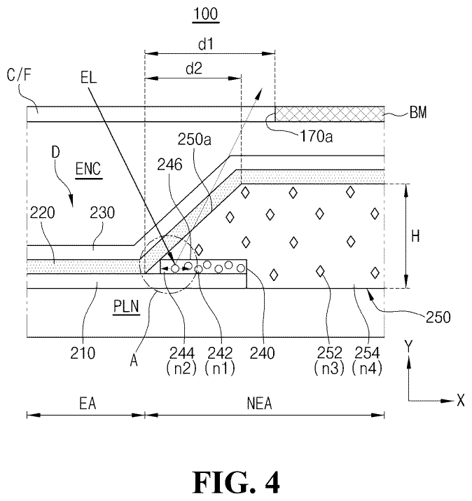

In an embodiment, a side 250a (FIG. 3) of the bank layer 250 adjacent to the emission area EA and covering the first electrode 210 and the light-diffusion coating layer 240 can be further extended toward the emission area EA rather than a side 170a (FIG. 4) of the black matrix 170 adjacent to the emission area where the color filter layer 172 is disposed, but is not limited thereto.

In other words, the side 250a (FIG. 4) of the bank layer 250 adjacent to the emission area EA is disposed to extend toward the emission area EA rather than the side 170a (FIG. 4) of the black matrix 170 to have a so called ‘PullBack’ structure, but is not limited thereto. As used herein, the term ‘pull back distance’ may indicate a separation distance d1 between the side 170a of the black matrix 170 adjacent to the emission area EA and the side 250a of the bank layer 250 adjacent to the emission area EA.

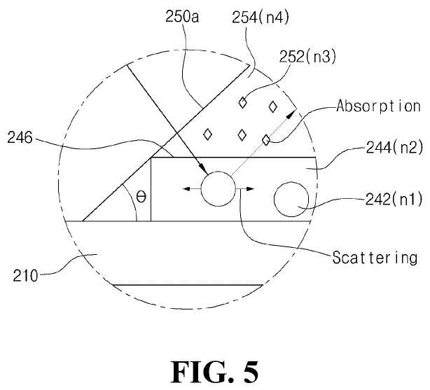

The components and arrangements of the light-emitting diode D, the light-diffusion coating layer 240 and the bank layer 250 will be described in more detail. FIG. 3 is a schematic diagram illustrating component and configurations of a light-emitting diode, a light-diffusion coating layer and a bank layer in the display device in accordance with the first embodiment of the present disclosure. FIG. 4 is a schematic diagram illustrating that the external light reflection is minimized in the display device in accordance with the first embodiment of the present disclosure. FIG. 5 is s schematic enlarged diagram the “A” area in FIG. 4.

Referring to FIG. 3, the light-diffusion coating layer 240 is disposed on the peripheral area of the first electrode 210 extended to the non-emission area NEA among the first electrode 210 constituting the light-emitting diode D. The light-diffusion coating layer 240 covers the surface of the peripheral area of the first electrode 210. The light-diffusion coating layer 240 includes a plurality of scattering particles 242 and a first binder resin 244 in which the plurality of scattering particles 242 are dispersed. The first binder resin 244 may be a first photosensitive binder resin.

In the first embodiment of the present disclosure, the light-diffusion coating layer 240 covering the peripheral area of the first electrode 210 has a surface 246 substantially parallel to the surface of the first electrode 210. Referring to FIG. 3, the surface 246 of the light-diffusion coating layer 240 may be disposed to extend along a first direction (x-axis direction).

The bank layer 250 is disposed on the peripheral area of the first electrode 210 and the light-diffusion coating layer 240. The bank layer 250 includes a light-blocking or light-absorbing material (hereinafter, ‘light-blocking material”) 252 and a second binder resin 254 in which the light-blocking material 252 is dispersed. The second binder resin 254 may be a second photosensitive binder resin.

Referring to FIGS. 4 and 5, the scattering particle 242 in the light-diffusion coating layer 240 may have a first refractive index n1 and the first binder resin 244 in which the plurality of scattering particles 242 are dispersed may have a second refractive index n2. The first refractive index n1 of the scattering particle 242 may differ from the second refractive index n2.

When the first refractive index n1 of the scattering particle 242 differs from the second refractive index n2 of the first binder resin 244, the external light EL incident to the light-diffusion coating layer 240 may collide with the scattering particles 242, and thus light scattering and diffusion may occur. For example, a difference between the first refractive index n1 of the scattering particle 242 and the second refractive index n2 of the first binder resin may be, but is not limited to, about 0.1 to about 2.0, for example, about 0.2 to about 2.0.

The light-blocking material 252 in the bank layer 250 may have a third refractive index n3 and the second binder resin 254 in which the plurality of light-blocking materials 252 are dispersed may have a fourth refractive index n4. The third refractive index n3 of the light-blocking material 252 may be substantially the same as the fourth refractive index n4 of the second binder resin 254. For example, a difference between the third refractive index n3 of the light-blocking material 252 and the fourth refractive index n4 of the second binder resin 254 may be equal to or less than about 0.2, for example, about 0.1.

The first refractive index n1 of the plurality of scattering particles 242 in the light-diffusion coating layer 240 may differ from the refractive indices n3 and/or n4 in the bank layer 250. For example, the first refractive index n1 of the scattering particle 242 may be different from the fourth refractive index n4 of the second binder resin 254 in the bank layer 250. In one embodiment, the second refractive index n2 of the first binder resin 244 may be substantially the same as the fourth refractive index n4 of the second binder resin 254.

In another embodiment, the difference between the first refractive index n1 of the scatting particle 242, and the third refractive index n3 of the light-blocking material 252 and/or the fourth refractive index n4 of the second binder resin 254 may be, but is not limited to, about 0.1 to about 2.0, for example, about 0.2 to about 2.0.

For example, the second refractive index n2 of the first binder resin 244, the fourth refractive index n4 of the second binder resin 254, and optionally, the third refractive index n3 of the light-blocking material 252 may be, but is not limited to about 1.50 to about 1.70, for example, about 1.55 to about 1.65, respectively.

In one embodiment, the first refractive index n1 of the scattering particle 242 may be higher than the second refractive index n2 of the first binder resin 244, the third refractive index n3 of the light-blocking material 252 and/or the fourth refractive index n4 of the second binder resin 254. In other words, the scattering particle 242 may have a higher refractive index than the first binder resin 244, the light-blocking material 252 and/or the second binder resin 254. For example, the first refractive index n1 of the scattering particle 242 may be, but is not limited to, about 1.75 to about 3.5, for example, about 1.80 to about 3.0. In one embodiment, the scattering particle 242 with the high-refractive index may include, but is not limited to, the following inorganic oxide particle such as metal oxide particle and the like.

In another embodiment, the first refractive index n1 of the scattering particle 242 may be lower than the second refractive index n2 of the first binder resin 244, the third refractive index n3 of the light-blocking material 252 and/or the fourth refractive index n4 of the second binder resin 254. In other words, the scattering particle 242 may have a lower refractive index than the first binder resin 244, the light-blocking material 252 and/or the second binder resin 254. For example, the first refractive index n1 of the scattering particle 242 may be, but is not limited to, about 1.05 to about 1.5, for example, about 1.05 to about 1.45. In one embodiment, the scattering particle 242 with the low-refractive index may include, but is not limited to, the following inorganic particle such as metal fluoride particle and/or silicon oxide particle.

In another embodiment, the scattering particle 242 with the low-refractive index may have a hollow structure. When the scattering particle 242 has the hollow structure, the first refractive index n1 of the scattering particle 242 may be further lower than the second refractive index n2 of the first binder resin 244, the third refractive index n3 of the light-blocking material 252 and/or the fourth refractive index n4 of the second binder resin 254. For example, the scattering particle 242 with the hollow structure may include, but is not limited to, the following metal fluoride particle and/or silicon oxide particle with the hollow structure.

In another embodiment, the scattering particle 242 may have a surface with a porous structure where plural pores are disposed. When the surface of the scattering particle 242 has the porous structure with the plural pores, the external light EL entering the light-diffusion coating layer 240 may be incident through the pores formed on the surface of the scattering particle 242, and may be dissipated with repeatedly reflection and/or scattering inside the scatting particle 242.

When the external light EL incidents to the plurality of scattering particles 242 dispersed in the light-diffusion coating layer 240 through the bank layer 250, light scattering and diffusion caused by the difference between the second refractive index n2 of the first binder resin 244 and/or the refractive indices n3 and n4 in the bank layer 250, and the first refractive index n1 of the scattering particle 242 may be occurred among the plurality of scattering particles 242. The external light EL diffused inside the light-diffusion coating layer 240 incidents back to the bank layer 250, and then may be absorbed by the light-blocking material 252 dispersed within the bank layer 250.

In another embodiment, the second refractive index n2 of the first binder resin 244 may be equal to or more than the fourth refractive index n4 of the second binder resin 254 and/or the third refractive index n3 of the light-blocking material 252. In this case, when the external light EL enters the light-diffusion coating layer 240 including the first binder resin 244 from the bank layer 250 including the second binder resin 254, the external light EL can be incident to the light-diffusion coating layer 240 without a total reflection.

The external light EL incident to the light-diffusion coating layer 240 from the bank layer 250 without the total reflection may collide with the scattering particles 242. As described above, the first refractive index n1 of the scatting particle 242 differs from the second refractive index n2 of the first binder resin 244, the third refractive index n3 of the light-blocking material 252 and/or the fourth refractive index n4 of the second binder resin 254. Accordingly, when the external light EL collides with the scattering particle 242, the considerable amount of the external light EL may be absorbed by the light-blocking material 252 as the external light EL scatters and diffuses. As the reflection of the externa light EL decreases, the rainbow stains and/or diffraction mura due to the reflection of the external light EL may be minimized.

In another embodiment, a refractive index of the encapsulation layer ENC may be substantially the same as the second refractive index n2 of the first binder resin 244 and/or the fourth refractive index n4 of the second binder resin 254. For example, a difference between the refractive index of the encapsulation layer ENC, and the second refractive index n2 of the first binder resin 244 and/or the fourth refractive index n4 of the second binder resin 254 may be, but is not limited to, be equal to or less than about 0.2 or less, for example, about 0.1 or less.

Each of the first binder resin 244 and the second binder resin 254 may be any photosensitive resin capable of applying to a photoresist (PR) process. For example, each of the first binder resin 244 and the second binder resin 254 can include independently, but is not limited to, a (meth) acrylate-containing resin, an acryl-containing resin, a cardo-containing resin, an epoxy-containing resin, an amide-containing resin, a urethane-containing resin, an acrylamide-containing resin, an imide-containing resin, a fluorene-containing resin, a siloxane-containing resin, copolymers thereof and combinations thereof.

The light-blocking material 252 in the bank layer 250 may include a black materials capable of absorbing light such as a black dye and/or a black pigment, and/or light-shielding materials. For example, the light-blocking material 252 may include, but is not limited to, a carbon black, carbon nano-tube (CNT), graphene, an organic black, a black pigment, a perylene-containing material, an azo-containing materials, a nano-based carbon material, a hybrid form of a red (R)/green (G)/blue (B) pigments/dyes and a multi-layered thin film material. In another embodiment, the light-blocking material 252 may include an organic material that is converted to black color by oxidization in a post-baking process.

The light-diffusion coating layer 240 and the bank layer 250 may be disposed on the peripheral area of the first electrode 210, on the planarization layer PLN and/or on the light-diffusion coating layer 240 using the photoresist (PR) process in which a photosensitive composition including a first or second binder resin 244 or 254 of the photosensitive binder resin, a solvent, the scattering particle 242 or the light-blocking material 252 and an additive such as dispersant is coated on the surface of the peripheral area of the first electrode 210, the planarization layer PLN and/or the light-diffusion coating layer 240, respectively, and a mask is used. In one embodiment, the light-diffusion coating layer 240 and the bank layer 250 may be disposed on the peripheral area of the first electrode 210, the planarization layer PLN and the light-diffusion coating layer 240, respectively through a negative process using the mask.

In one embodiment, the side 250a of the bank layer 250 in contact with the side of the light-emitting diode D may have a cross-sectional shape inclined downwardly toward the emissive layer 220. In other words, the side 250a of the bank layer 250 may have a cross-sectional shape of which width gradually increases toward the first electrode 210, i.e., a tapered cross-sectional shape.

In one embodiment, the side 250a of the bank layer 250 may be curved with a predetermined curvature or extended downwardly without the curvature. For example, the side 250a of the bank layer 250 can be disposed with an angle θ between about 30° and about 90°, for example, about 30° and about 60°, but is not limited thereto. As the side 250a of the bank layer 250 has the tapered cross-sectional shape, the occurrence of a dead point in the light-emitting diode D may be minimized and disconnection or lifting in the light-emitting diode D may be prevented.

In one exemplary embodiment, a height H of the bank layer 250 may be, but is not limited to, about 1 μm to about 5 μm, for example, about 1 μm to about 3 μm. In addition, the side 250a of the bank layer 250 in contact with the light-emitting diode D may extend toward the emission area EA with the pullback distance d1 compared to the side 170a of the black matrix BM in contact with a side of the color filter layer C/F. With the pullback distance, the viewing angle luminance and viewing angle properties of the display device 100 may be improved.

For example, the pullback distance d1 may be, but is not limited to, about 5 μm to about 10 μm. In another embodiment, a distance d2 between the side 250a of the bank layer 250 and the edge of the first electrode 210 may be, but is not limited to, about 1 μm to about 5 μm.

An ambient light diffraction mura due to the step difference caused by the thin film transistor Tr may occur. Also, as the diffraction of the reflected external light EL is further enhanced by the color filter layer C/F, a rainbow mura may occur due to interference between adjacent sub-pixel areas. In addition, the rainbow mura may be caused by the light reflection occurred in the conductive materials such as a conductive film and/or the electrode in the display panel and the refractive index differences between the films where the reflected light passes through.

In accordance with the first embodiment, the light-diffusion coating layer 240, which includes the scattering particle 242 and the first binder resin 244, and of which the surface 246 extends parallel to the surface of the first electrode 210, is intervened or disposed between the surface of the peripheral area of the first electrode 210 of the anode and the bank layer 250 including the light-blocking material 252. The external light EL incident to the light-diffusion coating layer 240 is scattered and diffused by the scattering particle 242 and is absorbed by the light-blocking material 252 in the bank layer 250.

When the bank layer 250 includes scattering particles, the external light EL scattered in the area adjacent to the surface of the bank layer 250 may be exposed to outside. However, in accordance with the embodiment, the light-diffusion coating layer 240 including the scattering particle 242 diffusing the external light EL is disposed between the first electrode 210 and the bank layer 250. The scattering particles 242 are dispersed in the light-diffusion coating layer 240 that is separately disposed from the bank layer 250. Accordingly, the external light EL scattered from the scattering particle 242 can be efficiently scattered and diffused inside the light-diffusion coating layer 240 and thereby minimizing the possibility of the external light EL being exposed to the outside.

Since considerable amount of the external light EL incident on the light-diffusion coating layer 240 is not incident on the first electrode 210 due to scattering and diffusion by the scattering particle 242 and to absorption by the light-blocking material 252, the amount of the external light EL incident on the first electrode 210 is greatly reduced. Accordingly, the amount of the external light EL reflected from the first electrode 210 and stains, for example, circular stains such as a rainbow mura and/or a diffraction mura, caused by the external light may be prevented or minimized.

In accordance with the present disclosure, the light-diffusion coating layer 240 in which the scattering particles 242 are dispersed is disposed on the peripheral area of the first electrode 210, independently from the bank layer 250 in which the light-blocking material 252 is dispersed. When the content of the light-blocking material 252 in the bank layer 250 increases, a free volume in the finally cured bank layer 250 increases. When the free volume increases, the amount of fume and outgas increases in curing the bank layer 250. When verifying the reliability of a product, outgas due to high-temperature treatment process increases, making the product vulnerable to reliability.

Accordingly, the content of the light-blocking material and particles dispersed in the bank layer 250 should be reduced or minimized to reduce the free volume and minimize the occurrence of the outgas. When the scattering particles are included in the bank layer 250 separately from the light-diffusion coating layer 240, the free volume and the amount of the outgas increases, and thus the bank layer 250 vulnerable to reliability is disposed.

However, the light-diffusion coating layer 240 in which the scatting particles 242 are dispersed is disposed only on the area where the light-reflection by the first electrode 210 may be reduced, for example, the pullback area, independently of the bank layer 250. Since the scattering particles 242 are not dispersed in the bank layer 250 other than the light-blocking material 252, the free volume and the amount of the outgas in the bank layer 250 do not increase.

Since the scatting particles 242 are not additionally added to the bank layer 250, an addition amount of the particles in the bank layer 250 may be reduced and the content of the second binder resin 254 may be relatively increased. It is possible to prevent a foreign material from remaining in the bank layer 250. Accordingly, process reliability of the bank layer 250 can be secured, and the external light EL reflection can be efficiently suppressed by the light-diffusion coating layer 240 including the scattering particles 242 in the pullback area related to the reflection of the first electrode 210.

In addition, when the content of light-blocking material 252 in the bank layer 250 increases, the development of the bank layer 250 does not occur well in a developing process performed after exposure in the photoresist (PR) process. Accordingly, a residual film remains on the substrate or the pattern of the bank layer 250 is not properly formed.

That is, when the bank layer 250 is developed, the chain of the second binder resin 254 that is not cured without reacting to a light source (e.g. UV) used in the exposure process attract the light-blocking material 252. Accordingly, while the content of the second binder resin 254 as a polymer material decreases and the content of the light-blocking material 252 increases, some of the light-blocking material 252 remains a residual film in the development process.

When the scatting particles 242 are included in the bank layer 250 in addition to the light-blocking material 252, the content of a particle-type material other than the second binder resin 254 is increased in the bank layer 250. In this case, while the developing process for the bank layer 250 does not occur efficiently, poor pattern formation of the bank layer 250 may occur or a residual film may be further generated.

However, the light-diffusion coating layer 240 in which the scattering particles 242 are dispersed is dispersed only in the area where the reflection of the first electrode 210 may be reduced, for example, the pullback area, independently from the bank layer 250. Since the scattering particles 242 are not dispersed in the bank layer 250 other than the light-blocking material 252, processability for the bank layer 250 may be secured, and reflection of the external light EL in the pullback area related to the reflection of the first electrode 210 can be efficiently suppressed by the light-diffusion coating layer 240 including the scattering particles 242.

In one embodiment, the scattering particle 242 may include an inorganic oxide particle, inorganic fluoride particle and combinations thereof. For example, the inorganic oxide particle of the scattering particle 242 may be selected from, but is not limited to, silicon monoxide (SiO), silicon dioxide (SiO₂), aluminum oxide (Al₂O₃), magnesium oxide (MgO), hafnium oxide (HfO₂), lutetium oxide (LuO₂), molybdenum oxide (MoO₃), niobium pentoxide (Nb₂O₅), scandium oxide (Sc₂O₃), tantalum pentoxide (Ta₂O₅), tungsten oxide (WO₃), yttrium oxide (Y₂O₃), tellurium oxide (TeO₂), titanium oxide (TiO₂), vanadium oxide (VO₂), zinc oxide (ZnO), zirconium oxide (ZrO₂), lutetium aluminum oxide (Lu₃Al₅O₁₂), scandium aluminum magnesium oxide (ScAlMgO₄), terbium gallium oxide (Tb₃Ga₅O₁₂), yttrium aluminum oxide (Y₃Al₅O₁₂), and combinations thereof.

For example, the inorganic fluoride particle of the scattering particle 242 may be selected from, but is not limited to, magnesium fluoride (MgF₂), lithium fluoride (LiF), potassium fluoride (KF), lithium calcium aluminum fluoride (LiCaAlF₆), sodium fluoride (NaF), rubidium fluoride (RbF), strontium fluoride (SrF₂), and combinations thereof.

In another embodiment, the scattering particle 242 may have an average size of about 100 nm to about 1000 nm, for example, about 100 nm to about 700 nm or about 100 nm to about 500 nm, but is not limited thereto. When the average size of the scattering particle 242 satisfies the above-described ranges, the external light EL incident to the light-diffusion coating layer 240 may be efficiently scattered and diffused with colliding with the scattering particles 242.

In accordance with the first embodiment, the stains due to the reflection of the external light EL may be prevented with improving the reliability and processability for the bank layer 250. As a polarizing member is not used, the luminance of the display device 100 is not reduced. Accordingly, it is possible to manufacture the display device 100 implementing ESG by inducing efficient light emission in low-power.

### Second Embodiment

FIG. 6 illustrates a schematic cross-sectional view of the display device in a second embodiment of the present disclosure.

Referring to FIG. 6, a display device 300 in accordance with the second embodiment includes a substrate 302 having the emission area EA and the non-emission area NEA, a thin film transistor Tr, a light-emitting diode D, a light-diffusion coating layer 440 and a bank layer 450 disposed on the substrate 302, and may include a black matrix 370 and a color filter layer 372 disposed on the light-emitting diode D.

The pixel region P (FIG. 1) including the red sub-pixel, the green sub-pixel, the blue sub-pixel, and optionally, the white sub-pixel may be defined in the substrate 302.

The thin film transistor Tr is disposed on the substrate 302. The thin film transistor Tr includes a semiconductor layer 310, a gate electrode 314, a source electrode 330 and a drain electrode 332. The thin film transistor Tr may be the driving thin film transistor Td (FIG. 1).

The semiconductor layer 310 may be disposed directly on the substrate 302 or a first buffer layer that can be disposed on the substrate 302. A gate insulating layer 312 may be disposed on the semiconductor layer 310 with covering the entire substrate 302. The gate electrode 314 including the conductive material is disposed on the gate insulating layer 312 corresponding to the central area of the semiconductor layer 310. In another embodiment, the gate insulating layer 312 may be patterned as the gate electrode 314.

An interlayer insulating layer 320 is disposed on the gate electrode 314. The interlayer insulating layer 320 may have first and second semiconductor contact holes 322 and 324 that expose or do not cover the both sides of the semiconductor layer 310. The first and second semiconductor contact holes 322 and 324 may be located spaced apart from the gate electrode 314 at both sides of the gate electrode 314.

The source electrode 330 and the drain electrode 332 including the conductive material such as metal are disposed on the interlayer insulating layer 320. The source electrode 330 and the drain electrode 332 are spaced apart from each other with centering the gate electrode 314, and contact to both sides of the semiconductor layer 310 through the first and second semiconductor contact holes 322 and 324.

A planarization layer 334 is disposed on the source electrode 330 and the drain electrode 332 with covering the entire substrate 302. The planarization layer 334 has a drain contact hole 336 that exposes or do not cover the drain electrode 332.

The light-emitting diode D comprises a first electrode 410 disposed on the planarization layer 334 and connected to the source electrode 330 or the drain electrode 332, and an emissive layer 420 and a second electrode 430 that are laminated sequentially on the first electrode 410.

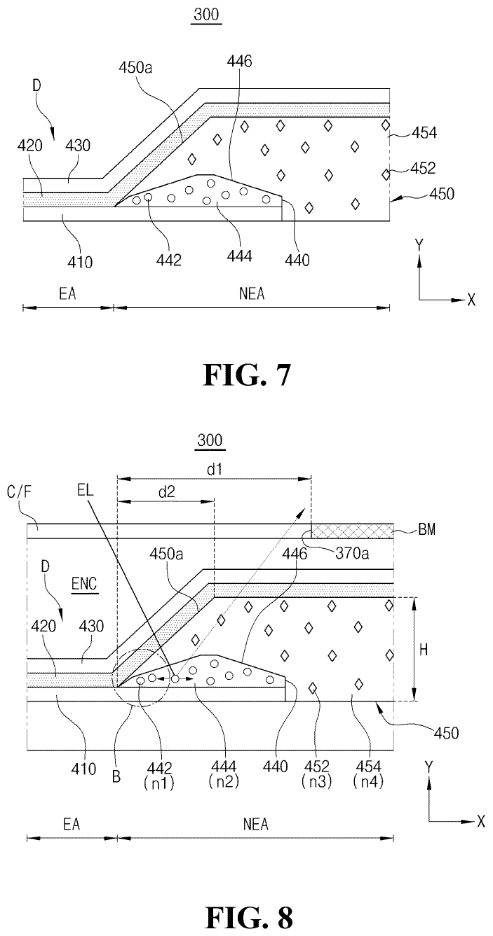

In addition, a light-diffusion coating layer 440 covering the peripheral area of the first electrode 410 and the bank layer 450 covering the peripheral area of the first electrode 410 and the light-diffusion coating layer 440 are disposed on the planarization layer 334. In accordance with the second embodiment, the light-diffusion coating layer 440 including scattering particles 442 is disposed between the peripheral surface of the first electrode 410 constituting the light-emitting diode D and the bank layer 450. A surface 446 (FIG. 7) of the light-diffusion coating layer 440 may have a cross-sectional shape protruded upwardly toward the bank layer 450.

A column spacer 340 is disposed on the bank layer 450. In one embodiment, the column spacer 340 may have a cross-sectional shape of which the width gradually increases toward the bank layer 450 (a trapezoidal cross-sectional shape or a tapered shaped), or a cross-sectional shape of which the width gradually decreases toward the bank layer 450 (an inverted-trapezoidal cross-sectional shape or an inverted-taper shape), but is not limited thereto.

An encapsulation layer 350 is disposed on the second electrode 430 in order to prevent external oxygen and/or moisture from infiltrating to the light-emitting diode D. The encapsulation layer 350 may have a lamination structure of a first inorganic insulating layer 352, an organic insulating layer 354 and a second inorganic insulating layer 356, but is not limited thereto.

A touch sensor including a connection electrode 362, a first touch insulating layer 364a, a second touch insulating layer 364b, a first touch electrode 366 and a second touch electrode 368 may be disposed on the encapsulation layer 350. In some embodiment, the touch sensor may be omitted.

A black matrix 370 and the color filter layer 372 are disposed on the encapsulation layer 350 or the second touch insulating layer 364b. A first insulating layer 380 may be disposed on the color filter layer 372. Alternatively, or additionally, a second insulating layer may be disposed on the first insulating layer 380.

In one embodiment, a side 450a (FIG. 7) of the bank layer 450 adjacent to the emission area EA is disposed to extend toward the emission area EA rather than a side 370a (FIG. 8) of the black matrix 370 to have a so called ‘pullback’ structure, but is not limited thereto.

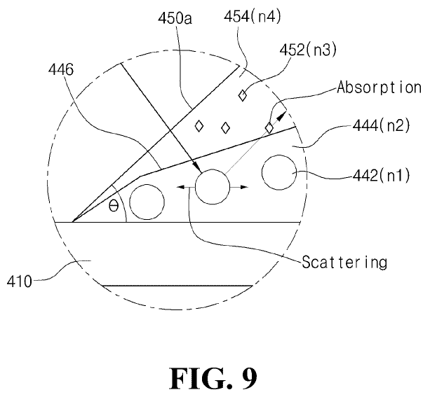

The components and arrangements of the light-emitting diode D, the light-diffusion coating layer 440 and the bank layer 450 will be described in more detail. FIG. 7 is s schematic diagram illustrating components and configurations of a light-emitting diode, a light-diffusion coating layer and a bank layer in the display device in accordance with the second embodiment of the present disclosure. FIG. 8 is a schematic diagram illustrating that the external light reflection is minimized in the display device in accordance with the second embodiment of the present disclosure. FIG. 9 is s schematic enlarged diagram the “B” area in FIG. 8.

Referring to FIG. 7, the light-diffusion coating layer 440 is disposed on the peripheral area of the first electrode 410 extended to the non-emission area NEA among the first electrode 410. The light-diffusion coating layer 440 covers the peripheral surface of the first electrode 410. The light-diffusion coating layer 440 includes a plurality of scatting particles 442 and a first binder resin 444 in which the plurality of scattering particles are dispersed. The scattering particle 442 may have the first refractive index n1 and the first binder resin 444 may have the second refractive index n2.

In the second embodiment, the surface 446 of the light-diffusion coating layer 440 covering the peripheral area of the first electrode 410 has a cross-sectional shape protruded upwardly (y-axis direction) toward the bank layer 450. For example, the surface 446 of the light-diffusion coating layer 440 may have a left surface of which thickness gradually increases so as to substantially correspond to the side 450a of the bank layer 450 in contact with the side of the emissive layer 420 constituting the light-emitting diode D, and a right surface of which thickness gradually decreases so as to substantially have a mirror shape with respect to the left surface. For example, the surface 446 of the light-diffusion coating layer 440 may have a wedge-shaped cross-section, but is not limited thereto.

The bank layer 450 includes a light-blocking material 452 and a second binder resin 454 in which the light-blocking material 452 is dispersed. The light-blocking material 452 may have the third refractive index n3 and the second binder resin 454 may have the fourth refractive index n4.

In one embodiment, the side 450a of the bank layer 450 that is disposed in contact with the side of the light emitting diode D may have a cross-sectional shape inclined downwardly toward the emissive layer 420. In other words, the side 450a of the bank layer 450 may have a cross-sectional shape of which the width increases toward the first electrode 410, that is, a tapered cross-sectional shape.

The first refractive index n1, the size and the materials of the scattering particle 442, the second refractive index n2 and the materials of the first binder resin 444, the third refractive index n3 and the materials of the light-blocking material 452, the fourth refractive index n4 and the materials of the second binder resin 454, the inclined angle θ of the side 450a of the bank layer 450 in contact with the light-emitting diode D, the pullback distance d1 and the distance d2 between the side 450a of the bank layer 450 and the edge of the first electrode 410 may be substantially the same with referring to FIGS. 2 to 5.

In accordance with the second embodiment, the light-diffusion coating layer 440, which includes the scatting particle 442 and the first binder resin 444, and of which the surface 446 has the cross-sectional shape protruded upwardly, is intervened or disposed between the peripheral surface of the first electrode 410 and the bank layer 450. The external light EL incident to the light-diffusion coating layer 440 is scattered and diffused by the scattering particle 442 and is absorbed by the light-blocking material 452 in the bank layer 450.

The side 450a of the bank layer 450 in contact with the side of the light-emitting diode D may have a taper-shaped cross-section inclined with the predetermined angle θ with respect to the surface of the first electrode 410. The surface 446 of the light-diffusion coating layer 440 has a cross-sectional shape protruding upwardly to substantially correspond to the side 450a of the bank layer 450 having a smaller surface area than other regions of the bank layer 450. Accordingly, when the external light EL incident on the side 450a of the bank layer 450 passes through the bank layer 450 and enters the light-diffusion coating layer 440, the external light EL may be efficiently scattered and diffused by the scattering particles 442 dispersed around the upwardly protruding cross-sectional surface 446.

Since considerable amount of the external light EL incident on the light-diffusion coating layer 440 is not incident on the first electrode 410 due to scattering and diffusion by the scattering particle 442 and to absorption by the light-blocking material 452, the amount of the external light EL incident on the first electrode 410 is greatly reduced. Accordingly, the amount of the external light EL reflected from the first electrode 410 and stains, for example, circular stains such as a rainbow mura and/or a diffraction mura, caused by the external light EL may be prevented or minimized.

The light-diffusion coating layer 440 including the plurality of scattering particles 442 is intervened or disposed between the first electrode 410 and the bank layer 450. In other words, the bank layer 450 does not include any scattering particle 442 other than the light-blocking material 452. Accordingly, the process reliability and processability for the bank layer 450 are not deteriorated by arranging the light-diffusion coating layer 440 including the scattering particles 442 only in the pullback region related to the reflection of the first electrode 410. It is possible to efficiently prevent the reflection of the external light EL and to reduce or minimize circular stains, rainbow mura and/or diffraction mura caused by the reflection of the external light EL. In addition, the luminance of the display device 300 does not decrease by removing the polarizing member. Efficient light emission can be implemented at low-power.

### Third Embodiment

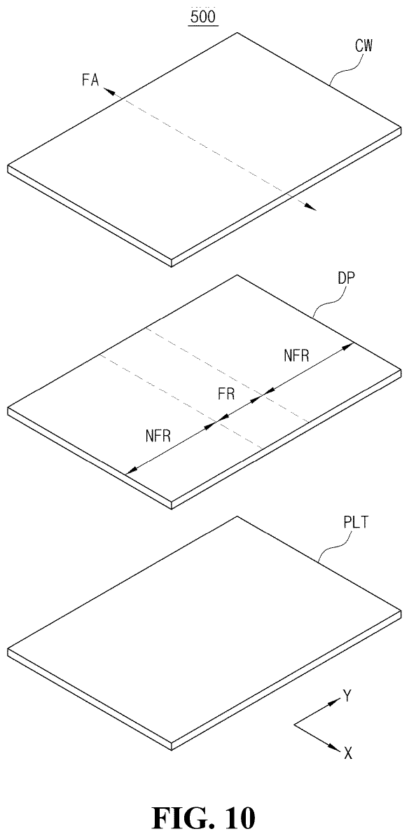

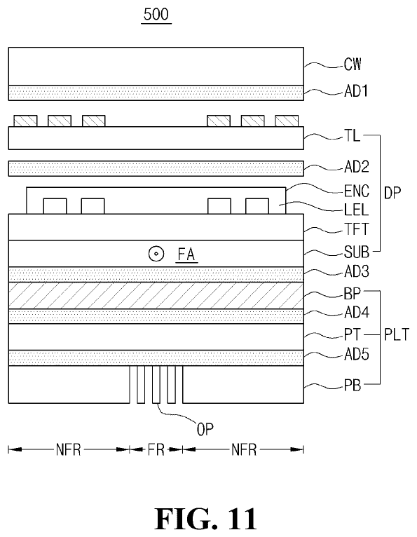

In one embodiment, the display device of the present disclosure may be a foldable display device. FIG. 10 illustrates a schematic exploded perspective view of a display device in accordance with a third embodiment of the present disclosure. FIG. 11 illustrates a schematic cross-sectional view of the display device in accordance with the third embodiment of the present disclosure.

Referring to FIGS. 10 and 11, a display device 500 includes a folding region FR and a non-folding region NFR, and can be folded along a first direction (y-axis direction). The display device 500 may comprise the non-folding region NFR at both sides of the folding region FR along the first direction.

The display device 500 may be out-folded in which the display surface is exposed to the outside when implementing the folding state, but is not limited thereto. Alternatively, or additionally, the display device 500 may be in-folded in which the display surface is hidden therein.

In one embodiment, a display panel DP may be folded inwardly or outwardly with respect to a folding axis FA. In the present disclosure, the folding axis FA represents a center of the folding area having a predetermined curvature due to folding by an imaginary line. While the display panel DP is illustrated to be folded at a center portion in FIG. 10, the entire portion of the display panel DP may be freely deformed.

The display panel DP may include a substrate SUB including a flexible material so that the display area may be folded inwardly or outwardly, and an element layer for displaying an image. For example, the element layer may include a thin film transistor element layer TFT and a light emitting element layer LEL disposed in the display area on the substrate SUB.

An encapsulation layer ENC is disposed on the light emitting element layer LEL, touch layer (touch sensor) TL is disposed on the encapsulation layer ENC, and a cover window CW is disposed on the touch layer TL. In addition, a color filter layer and/or a black matrix may be disposed on the touch layer TL, for example, between the touch layer TL and the cover window CW.

A plate PLT is disposed on the lower surface of the substrate SUB for supporting the substrate SUB. For example, the plate PLT may comprise a back plate BP, a plate top PT and a plate bottom PB disposed sequentially on the lower surface of the substrate SUB.

The thin film transistor element layer TFT includes a thin film transistor with a semiconductor layer, a gate electrode, a source electrode and a drain electrode, a gate insulating layer and an interlayer insulating layer. The thin film transistor may have the structure illustrated in FIG. 2 or FIG. 6. The thin film transistor may be a driving thin film transistor and may comprise an oxide semiconductor.

The light emitting element layer LEL may comprise the light-emitting diode D, the light-diffusion coating layer 240 or 440, the bank layer 250 or 450 and the column spacer 140 or 340. The arrangements and/or shapes of the light-emitting diode, the light-diffusion coating layer, the bank layer, and/or the column spacer may be the same referring to FIGS. 2 to 9.

The substrate SUB on which the thin film transistor element layer TFT and the light emitting element layer LEL are disposed may be encapsulated by the encapsulation layer ENC. The encapsulation layer ENC prevents external oxygen and/or moisture from infiltrating to the light emitting element layer LEL.

The cover window CW constitutes an outer periphery of the display device 500. The cover window CW may be positioned outside the surface on which the image is displayed on the display panel DP, transmits the images of the display panel DP, and protects the display panel DP from external impact or stress.

The cover window CW may comprise a reinforced glass and/or a reinforced plastic material. For example, the cover window CW may include, but is not limited to, a material selected from high-strength reinforced glass, polyethylene terephthalate (PET), acrylic resins and/or (meth) acrylate resins such as polymethyl methacrylate (PMMA) to prevent scratches form the outside.

The back plate BP may comprise an organic material with beneficial folding properties. For example, the back plate BP can comprise, but is not limited to, a polyimide (PI).

The plate top PT and the plate bottom PB may comprise a metal component, and the thickness of the plate bottom PB exposed to the outside may be larger than the thickness of the plate top PT. For example, the plate top PT may comprise SUS301 with relatively high hardness and the plate bottom PB may comprise SUS313 with higher corrosion resistance and acid resistance, but is not limited thereto.

The plate bottom PB comprises a plurality of openings OP in the folding area FR so that the display device 500 can improve the folding property. In one embodiment, the plurality of openings OP may be configured to penetrate the surface and/or rear surface of the plate bottom PB.

A plurality of adhesive components AD1, AD2, AD3, AD4 and AD5 may be disposed among the plurality of components in the display device 500. For example, a first adhesive component AD1 may be disposed between the touch layer TL and the cover window CW, a second adhesive component AD2 may be disposed between the encapsulation layer ENC and the touch layer TL, a third adhesive component AD3 may be disposed between the substrate SUB and the back plate BP, a fourth adhesive component AD4 may be disposed between the back plate BP and the plate top PT, and a fifth adhesive component AD5 may be disposed between the plate top PT and the plate bottom PB. Each of the first to fifth adhesive components AD1, AD2, AD3, AD4 and AD5 may comprise an optically clear adhesive (OCA) and/or a pressure sensitive adhesive (PSA).

In accordance with the third embodiment, it is possible to reduce or minimize the stains caused by the reflection of external light, and to implement the display device with beneficial luminous efficiency. In addition, the foldable display with beneficial flexibility by omitting a polarizer may be fabricated. The display device implementing ESG can be manufactured with the advantages of low reflection and low power.

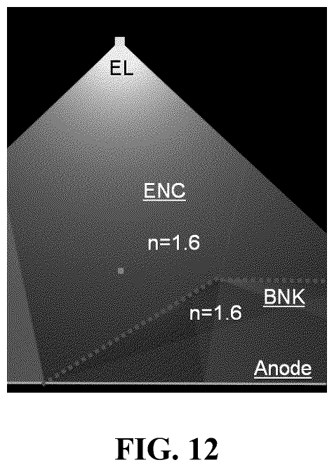

FIGS. 12 to 14 are photographs illustrating simulation results for the reflection of external light in the display device where no light-diffusion coating layer is disposed on the surface of the first electrode constituting the light-emitting diode and in the display device where the light-diffusion coating layer is disposed between the first electrode and the bank layer BNK. Each of the refractive index of the bank layer, the encapsulation layer ENC on the bank layer, the binder resin of the light-diffusion coating layer DCL is set to 1.6, and the refractive index of the scattering particle inside the light-diffusion coating layer DCL is set to 1.8.

Referring to FIG. 12, when the bank layer BNK covers the peripheral surface of the first anode of the first electrode without disposing a separate light-diffusion coating layer in which the scattering particles are dispersed on the surface of the anode constituting the light-emitting diode, considerable external light EL reflection occurs.

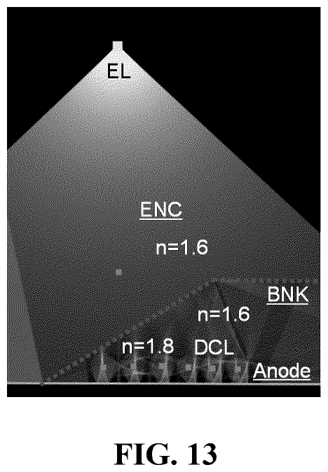

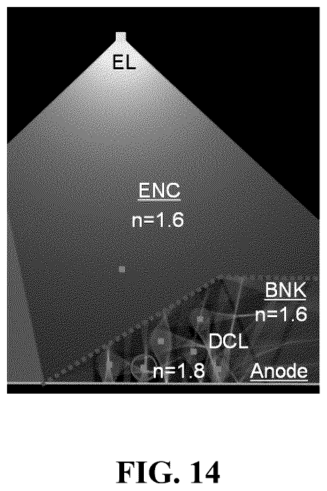

On the contrary, as illustrated in FIG. 13, when the light-diffusion coating layer DCL including the scattering particles is disposed parallel to the anode surface, or as illustrated in FIG. 14, when the light-diffusion coating layer DCL including the scattering particles is disposed on the anode surface to protrude upwardly, the incident external light EL is absorbed by the bank layer BNK including the black material to absorb the reflected external light by the anode. In addition, the reflectance of the external light EL decreases and the light diffusion increases due to the scattering particles, and thus stains caused by the external light EL may be improved.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. A display device, comprising:
a substrate having an emission area and a non-emission area;
a light-emitting diode disposed on the substrate correspondingly to the emission area, wherein the light-emitting diode includes a first electrode, a second electrode facing the first electrode, and an emissive layer between the first electrode and the second electrode;
a light-diffusion coating layer disposed on a peripheral area of the first electrode, wherein the light-diffusion coating layer includes a scattering particle, and a first binder resin in which the scattering particle is dispersed; and
a bank layer disposed correspondingly to the non-emission area outside of the light-emitting diode and covering the peripheral area of the first electrode and the light-diffusion coating layer.

2. The display device of claim 1, wherein the scattering particle has a refractive index different from a refractive index of the first binder resin.

3. The display device of claim 1, wherein the scattering particle has a refractive index different from a refractive index of the bank layer.

4. The display device of claim 1, wherein the scattering particle has a refractive index lower than refractive indices of the first binder resin and the bank layer.

5. The display device of claim 1, wherein the bank layer includes:
a light-blocking material; and
a second binder resin in which the light-blocking material is dispersed.

6. The display device of claim 5, wherein the scattering particle has a refractive index different from refractive indices of the first binder resin and the second binder resin, respectively.

7. The display device of claim 5, wherein the light-blocking material includes at least one of a black dye and a black pigment.

8. The display device of claim 5, wherein the first binder resin has a refractive index equal to or more than a refractive index of the second binder resin.

9. The display device of claim 1, wherein the light-diffusion coating layer has a surface configured to be parallel to a surface of the first electrode in a cross-section view.

10. The display device of claim 1, wherein the light-diffusion coating layer includes a surface with an upwardly protruding cross-sectional shape.

11. The display device of claim 1, wherein the scattering particle includes surfaces with a porous structure with a plurality of pores, or the scattering particle has a hollow structure.

12. The display device of claim 1, wherein the scattering particle comprises an inorganic oxide selected from silicon monoxide (SiO), silicon dioxide (SiO₂), aluminum oxide (Al₂O₃), magnesium oxide (MgO), hafnium oxide (HfO₂), lutetium oxide (LuO₂), molybdenum oxide (MoO₃), niobium pentoxide (Nb₂O₅), scandium oxide (Sc₂O₃), tantalum pentoxide (Ta₂O₅), tungsten oxide (WO₃), yttrium oxide (Y₂O₃), tellurium oxide (TeO₂), titanium oxide (TiO₂), vanadium oxide (VO₂), zinc oxide (ZnO), zirconium oxide (ZrO₂), lutetium aluminum oxide (Lu₃Al₅O₁₂), scandium aluminum magnesium oxide (ScAlMgO₄), terbium gallium oxide (Tb₃Ga₅O₁₂), yttrium aluminum oxide (Y₃Al₅O₁₂), and combinations thereof.

13. The display device of claim 1, wherein the scattering particle comprises an inorganic fluoride selected from magnesium fluoride (MgF₂), lithium fluoride (LiF), potassium fluoride (KF), lithium calcium aluminum fluoride (LiCaAlF₆), sodium fluoride (NaF), rubidium fluoride (RbF), strontium fluoride (SrF₂), and combinations thereof.

14. The display device of claim 1, wherein a difference between a refractive index of the scattering particle and a refractive index of the first binder resin is 0.1 to 2.0.

15. The display device of claim 6, wherein a difference between a refractive index of the scattering particle and a refractive index of the first binder resin and the second binder resin is 0.1 to 2.0, respectively.

16. The display device of claim 1, wherein the scattering particle has a refractive index between 1.75 and 3.5.

17. The display device of claim 1, wherein the scattering particle has an average size between 100 nm and 1000 nm.

18. The display device of claim 1, wherein the display device further comprises:
a driving thin film transistor disposed on the substrate and connected to the light-emitting diode;
an encapsulation layer disposed on the light-emitting diode and the bank layer;
a color filter layer disposed on the encapsulation layer correspondingly to the emission area; and
a black matrix disposed on the encapsulation layer correspondingly to the non-emission area.

19. The display device of claim 18, wherein a side of the bank layer in contact with the light-emitting diode extends toward the emission area compared to a side of the black matrix in contact with the color filter layer.

20. The display device of claim 18, wherein the driving thin film transistor includes an oxide semiconductor.
